(19) United States
(12) Patent Application Publication
(10) Pub. No.: US 2026/0353721 A1
(43) Pub. Date: Nov. 5, 2026

(54) SUPERJUNCTION TRANSISTOR DEVICE

(71) Applicant: Infineon Technologies AG, Neubiberg (DE)

(72) Inventors: Armin Willmeroth, Friedberg (DE); Caspar Leendertz, München (DE)

(21) Appl. No.: 19/662,006

(22) Filed: Apr. 29, 2026

(30) Foreign Application Priority Data
Apr. 30, 2025 (DE) 102025116849.0

(51) Int. Cl. H10D 62/10; H10D 30/66; H10D 62/00; H10D 62/60; H10D 62/832; H10D 84/83

(52) U.S. Cl. CPC H10D 62/111; H10D 62/054; H10D 62/60; H10D 84/839; H10D 30/668; H10D 62/8325

(57) ABSTRACT

A transistor device includes transistor cells at least partially integrated in a semiconductor body; a drain region of a first doping type arranged in the semiconductor body; and a superjunction region arranged in the semiconductor body and having first regions of a first doping type and second (complementary) regions of a second doping type. Each of the first and second regions extend in a first direction between the transistor cells and the drain region. Each first region has a first end section facing the drain region. Each second region has a second end section facing the drain region. In a pair of neighboring first and second regions, the first end section has a first effective amount of first type dopant atoms and the second end section has a second effective amount of second type dopant atoms, the second effective amount being at least 1.1 times the first effective amount.

### TECHNICAL FIELD

This disclosure relates in general to a superjunction transistor device, in particular a silicon carbide (SiC) superjunction device.

### BACKGROUND

A superjunction transistor device includes a superjunction region with a plurality of first regions of a first doping type (conductivity type) and coupled to a drain node, and a plurality of second regions of a second doping type (conductivity type) complementary to the first doping type and coupled to a source node. The first regions are often referred to as drift regions and the second regions are often referred to as compensation regions.

A superjunction transistor device further includes transistor cells coupled between the source node and the superjunction region, wherein the transistor cells can be operated in a conducting state (on-state) or a blocking state (off-state). In the conducting state, the superjunction device is operated such that a current can flow between the source node and the drain node through the first regions. In the blocking state, the superjunction device is operated such that pn-junctions between the first and second regions are reverse biased so that depletion regions (space charge regions) expand in the first and second regions.

A voltage blocking capability of the superjunction transistor device is defined by a maximum voltage that can be applied between the drain and source nodes without causing an Avalanche breakdown. An on-resistance of the superjunction transistor device is an electrical resistance between the source node and the drain node when the transistor device is in the on-state. The on-resistance is significantly dependent on the resistance of the first regions.

There is a need to reduce the on-resistance without reducing the voltage blocking capability.

### SUMMARY

One example relates to a transistor device. The transistor device includes a semiconductor body, a plurality of transistor cells each at least partially integrated in the semiconductor body, a drain region of a first doping type arranged in the semiconductor body, a superjunction region arranged in the semiconductor body and including a plurality of first regions of a first doping type and a plurality of second regions of a second doping type complementary to the first doping type. Each of the first and second regions extends in a first direction between the transistor cells and the drain region, each of the first regions includes a first end section facing the drain region, and each of second regions includes a second end section facing the drain region. In a pair of neighboring first and second regions, the first end section includes a first effective amount of first type dopant atoms and the second end section includes a second effective amount of second type dopant atoms, wherein the second effective amount is at least 1.1 times the first effective amount.

Another example relates to a transistor device. The transistor device includes a semiconductor body, a plurality of transistor cells each at least partially integrated in the semiconductor body, a drain region of a first doping type arranged in the semiconductor body, a superjunction region arranged in the semiconductor body and including a plurality of first regions of a first doping type and a plurality of second regions of a second doping type complementary to the first doping type. Each of the first and second regions extends in a first direction between the transistor cells and the drain region, each of the first regions includes a third end section facing the transistor cells, and each of the second regions includes a fourth end section facing the transistor cells. In a pair of neighboring first and second regions, the third end section includes a third effective amount of first type dopant atoms and the fourth end section includes a fourth effective amount of second type dopant atoms, wherein the fourth effective amount is at least 1.1 times the third effective amount.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 shows a vertical cross sectional view of a superjunction device according to one example, wherein the transistor device includes a superjunction with first and second regions and a plurality of transistor cells;

FIG. 2 shows a modification of the transistor device according to FIG. 1;

FIGS. 3A-3B illustrate transistor cells according to one example;

FIGS. 4A-4B illustrates transistor cells according to another example;

FIGS. 5A-5D illustrate one example of a method for producing the superjunction region;

FIGS. 6A-6B illustrate another example of a method for producing the superjunction region;

FIG. 7 illustrates a pair of neighboring first and second regions of the superjunction region in greater detail;

FIG. 8 schematically illustrates a doping profile of neighboring first and second regions according to one example;

FIG. 9 illustrates the electric field in a superjunction transistor device having a doping profile as illustrated in FIG. 8;

FIG. 10 illustrates a pair of neighboring first and second regions of the superjunction region in greater detail;

FIG. 11 schematically illustrates a doping profile of neighboring first and second regions according to one example;

FIG. 12 schematically illustrates a doping profile of a second regions according to one example;

FIG. 13 schematically illustrates a top view of a transistor device according to one example;

FIG. 14 schematically illustrates a top view of a transistor device according to another example;

FIG. 15 schematically illustrates a horizontal cross sectional view of a transistor device according to one example; and

FIG. 16 schematically illustrates a transistor device according to another example.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

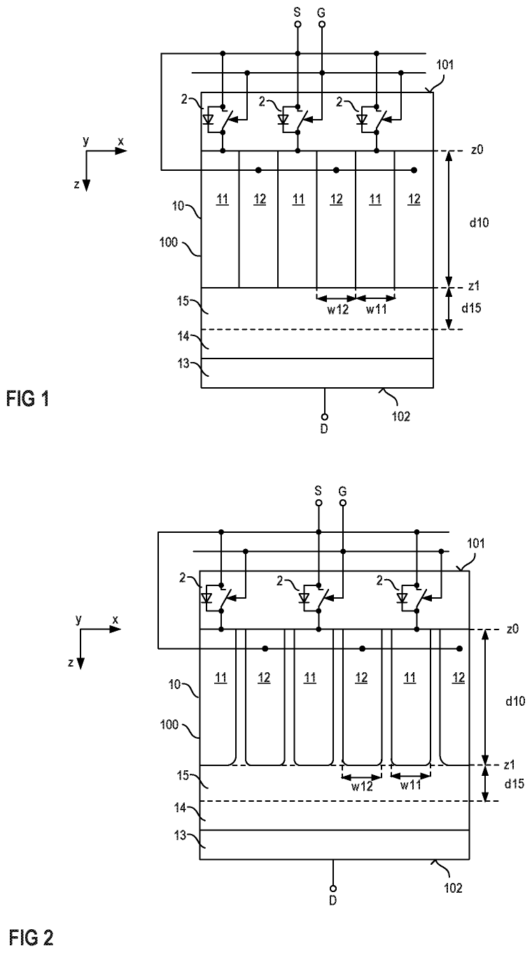

FIGS. 1 and 2 each schematically illustrate a superjunction transistor device. More specifically, each of FIGS. 1 and 2 schematically illustrates a cross-sectional view of one section of a semiconductor body 100 in which semiconductor regions of the respective superjunction transistor device are integrated.

Referring to FIGS. 1 and 2, the transistor device includes a superjunction region 10 that is arranged in the semiconductor body 100 and includes a plurality of first regions 11 of a first doping type (conductivity type) and a plurality of second region 12 of a second doping type (conductivity type) complementary to the first doping type. The first and second regions 11, 12 extend in a first direction z of the semiconductor body 100 and are arranged alternatingly in a second direction x of the semiconductor body 100. According to one example, the second direction x is perpendicular to the first direction z.

According to one example, the transistor device is a silicon carbide (SiC) transistor device. In this example, the semiconductor body 100 includes monocrystalline SiC. According to one example, the semiconductor body 100 includes SiC of the 6H poly type or 4H polytype.

According to one example illustrated in FIG. 1, neighboring first and second regions 11, 12 may adjoin one another. According to another example illustrated in FIG. 2, neighboring first and second regions 11, 12 are spaced apart from each other in the second direction x. Regions of the semiconductor body 100 arranged between the first and second regions 11, 12 have a doping concentration lower than the doping concentration of each of the first and second regions 11, 12, such as less than 0.2 (2E−1) times, less than 0.15 times, or less than 0.1 times the doping concentration of each of the first and second regions 11, 12.

Referring to FIGS. 1 and 2, the transistor device further includes a drain region 13 of the first doping type that is electrically coupled to each of the first regions 11. According to one example, the transistor device includes a buffer region 14 of the first doping type that is arranged between the superjunction region 10 and the drain region 13 and adjoins both the superjunction region 10 with the first and second regions 11, 12 and the drain region 14. In this example, the drain region 13 is electrically coupled to the first region 11 through the buffer region 14. According to one example, the buffer region 14 has a doping concentration that is lower than the doping concentration of the drain region 13 and higher than a maximum doping concentration of the first regions 11. According to another example (not illustrated), the drain region 13 adjoins the first regions 11, in order to be electrically coupled to the first regions 11.

According to one example, the doping concentration of the buffer region 14 is between 1E15 cm⁻³ and 1E19 cm⁻³. The buffer region 14 may have a lower doped section and a higher doped section arranged between the lower doped section and the drain region 13. The lower doped section may have a doping concentration in the range of between 1E15 cm⁻³ and 1E17 cm⁻³, and the higher doped section may have a doping concentration in the range of between 1E18 cm⁻³ and 1E19 cm⁻³.

Optionally (and illustrated in dashed lines in FIGS. 1 and 2) the transistor device further includes a drift region 15. The drift region 15 adjoins the superjunction region and is arranged between the superjunction region 10 and the buffer region 14. The optional drift region 15 is of the first doping type and has a doping concentration lower than the doping concentration of the first regions 11 of the superjunction region 10 and the drain region 13. According to one example, the drift region 15 has a doping concentration lower than the doping concentration of the buffer region 14. According to one example, the doping concentration of the drift region 15 is in a range of between 1E15 cm⁻³ and 5E17 cm⁻³ and the doping concentration of the buffer region 14 is in a range of between 1E17 cm⁻³ and 1E19 cm⁻³.

An overall length of the superjunction region 10 and the drift region 15 substantially defines the voltage blocking capability of the transistor device. The overall length is given by the length d10 of the superjunction region 10 plus the length d15 of the drift region 15. The length of the superjunction region 10 is the dimension of the superjunction region 10 in the vertical direction z, and the length d15 of the drift region 15 is the dimension of the drift region 15 in the vertical direction z.

Depending on the specific implementation, the voltage blocking capability of the transistor device is, e. g., between 650 V and 6.5 kV. In a SiC based transistor device with a voltage blocking capability of 650V, the overall length is between 4 micrometers (mm) and 6 micrometers, for example; and in a SiC based transistor device with a voltage blocking capability of 1.2 kV, the overall length is between 8 and 10 μm, for example.

According to one example, the length d10 of the superjunction region 10 is between 30% and70% of the overall length (d10+d15) of the superjunction region 10 and the drift region 15.

The drain region 13 is connected to a drain node D or forms the drain node D of the transistor device. Furthermore, each of the second regions 12 of the superjunction region 10 is connected to a source node S of the transistor devices. Connections between the second regions 12 and the source node S are only schematically illustrated in FIGS. 1 and 2. Examples for connecting the second regions 12 to the source node S are explained herein further below. The drain and source node D, S are circuit nodes or terminals of the transistor device that are configured to receive a load path voltage and a load current when the transistor device is in operation. This is basically known in a superjunction transistor device so that no further explanation is required in this regard.

Referring to FIGS. 1 and 2, the transistor device further includes a plurality of transistor cells 2. Each transistor cell 2 is coupled between the source node S and at least one of the first regions 11 of the superjunction region 10. Furthermore, each transistor cell 2 is configured to control a conducting channel between the source node S and the respective first region 11. The transistor cells 2 are not illustrated in detail in FIGS. 1 and 2. Instead, in FIGS. 1 and 2, each of the transistor cells 2 is represented by an electronic switch with a parallel diode. Detailed examples of the transistor cells 2 are explained herein further below.

Referring to FIGS. 1 and 2, the drain region 13 is spaced apart from the transistor cells in the first direction z, wherein the superjunction region 10 is arranged between the transistor cells 2 and the drain region 13. In the examples illustrated in FIGS. 1 and 2, the transistor device is a vertical transistor device. In this type of transistor device, the drain region 13 is spaced apart from the transistor cells 2 in a vertical direction of the semiconductor body 100. Thus, in the examples illustrated in FIGS. 1 and 2, the first direction z is a vertical direction of the semiconductor body 100. The “vertical direction” of the semiconductor body 100 is a direction that is essentially perpendicular to first and second (main) surfaces 101, 102 of the semiconductor body 100. According to one example, the transistor cells 2 are at least partially integrated in the semiconductor body 100 below the first surface 101, and the drain region 13 is arranged adjacent to the second surface 102.

In the vertical transistor devices illustrated in FIGS. 1 and 2, the second direction x, which is the direction in which the first and second regions 11, 12 of the superjunction region 10 are arranged alternatingly, is a lateral direction of the semiconductor body 100 and is referred to as first lateral direction in the following. In a second lateral direction y, which is a direction perpendicular to the first lateral direction x, the first and second regions 11, 12 of the superjunction region 10 may be elongated. Examples of elongated first and second 11, 12 are explained herein further below.

The transistor cells 2 can be operated in an on-state (conducting state) or an off-state (blocking state). The operating state of the transistor cells governs the operating state of the transistor device, so that the transistor device is in the on-state when the transistor cells are in the on-state and in the off-state when the transistor cells are in the off-state. In the on-state, the transistor cells 2 provide conducting channels between the source node S and the first regions 11. In the on-state of the transistor device, a current can flow between the drain node D and the source node S via the drain region 13, the optional buffer region 14, the first regions 11 of the superjunction region 10 and the conducting channels provided by the transistor cells 2. In the off-state, the transistor cells 2 interrupt the conducting channels between the source node S and the first regions 11. In the off-state of the transistor device, a current flow between the drain node D and the source node S is prevented.

Usually, each transistor cell 2 includes an integrated diode that bypasses the conducting channel controlled by the respective transistor cell 2. These integrated diodes, when forward biased, allow a current to flow through the transistor device between the drain node D and the source node S independent of the operating state of the transistor cells 2. An operating state of the transistor device in which the integrated diodes are conducting can be referred to as diode state. “On-state” and “off-state” as used herein are operating states of the transistor device in which the integrated diodes are reverse biased. That is, the drain-source voltage applied between the drain and source nodes D, S in the on-state or the off-state has a polarity opposite the polarity that forward biases the integrated diode.

The transistor cells 2 each include a gate electrode (not illustrated in detail in FIG. 1) connected to a gate node G of the transistor device. The transistor cells 2 are configured to operate in the on-state or the off-state dependent on a voltage (gate-source voltage) applied between the gate node G and the source node S. More specifically, the transistor cells 2 are in the on-state, for example, when the gate-source voltage has a voltage level higher than a threshold voltage of the transistor devices and in the off-state, for example, when the gate-source voltage has a voltage level lower than the threshold voltage.

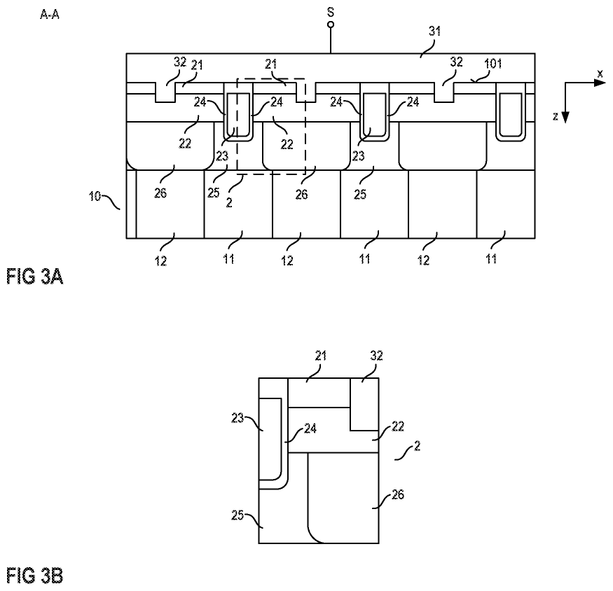

FIGS. 3A-3B illustrate transistor cells according to one example. More specifically, FIG. 3A shows a vertical cross-sectional view of several transistor cells 2, and FIG. 3B shows one transistor cell of the type illustrated in FIG. 3A in greater detail. Referring to FIGS. 3A-3B, each transistor cell includes a source region 21 of the first doping type and connected to the source node S, a body region 22 of the second doping type and adjoining the source region 21, and a gate electrode 23 adjacent to the body region 22 and dielectrically insulated from the semiconductor body 100 by a gate dielectric 24. The gate electrode 24 is connected to the gate node G and, in a conventional way, is configured to control a conducting channel in the body region 22 between the source region 21 and a respective first region 11 of the superjunction region 10. The transistor device is in the on-state when the gate electrodes 23 of the transistor cells 2 generate conducting channels in the body regions 22, and the transistor device is in the off-state, when the conducting channels are interrupted. Connections between the gate electrodes 23 and the gate G are not illustrated in FIGS. 3A-3B. An example for connecting the gate electrodes 23 to the gate node G is explained herein further below.

The gate electrodes 23 are arranged in trenches that extend from the first surface 101 into the semiconductor body 100. This, however, is only an example. It is also possible to implement the transistor cells 2 with planar gate electrodes formed above the first surface 101.

Referring to FIG. 3A, the source node S is formed by a source electrode 31 or is connected to a source electrode 31. The source electrode 31 is formed above the first surface 101 of the semiconductor body 100, is connected to the source regions 21, and is insulated from the gate electrodes 23. Furthermore, according to one example, the body regions 22 of the individual transistor cells 2 are connected to the source electrode 31. For this, the source electrode 31 may include electrically conducting vias 32 that extend through the source regions 21 to or into the body regions 22. The source electrode 31 includes an electrically conducting material such as, for example, a metal or highly doped polysilicon.

Referring to the above, the transistor cells 2 control electrically conducting channels between the source regions 21 and the first regions 11 of the superjunction region 10. According to one example (not illustrated) the first regions 11 of the superjunction region 10 adjoin the body regions 22. According to another example illustrated in FIGS. 3A-3B, current spreading regions 25 of the first doping type are arranged between the body regions 22 and the first regions 11. According to one example, the current spreading regions 25 have a higher doping concentration than the first regions 11. According to another example, the current spreading regions 25 have essentially the same doping concentration as the first regions 11, and may even have a lower doping concentration than the first regions 11.

PN junctions are formed between the body regions 22 and the current spreading regions 25 (or, alternatively, the first regions 11). These PN junctions form the integrated body diodes of the transistor cells 2. The transistor device is in the off-state when the conducting channels in the body regions 22 are interrupted and a voltage is applied between the drain node D and the source node S that reverse biases the PN junctions between the current spreading regions 25 and the body diodes 22.

According to one example, each transistor cell 2 further includes a shielding region 26 of the second doping type that is electrically connected to the source node S. In the example illustrated in FIGS. 3A-3B, each shielding region 26 adjoins a body region 22 and is connected to the source node S via the body region 22.

Referring to FIG. 3A, shielding regions 26 and current spreading regions 25 are arranged alternatingly in the first lateral direction x. Furthermore, a PN junction is formed between each shielding region 26 and the adjoining current spreading region 25. The shielding regions 26 and the current spreading regions 25 form JFET (Junction Field-Effect Transistor) structures which protect the gate dielectrics 24 from high electric fields when the transistor device is in the off-state. More specifically, when the transistor device is in the off-state the shielding regions 26, which are coupled to the source node S, deplete the current spreading regions 25, which are coupled to the drain node D via the first regions 11, of charge carriers. The depleted current spreading regions 25 protect the gate dielectrics 24 from high electric fields. According to one example, doping concentrations of the shielding region 26 are such that the shielding region 26 cannot entirely be depleted of charge carriers, so that at least portions of the shielding region 26 have an electrical potential that essentially equals the electrical potential of the source node S when the transistor device is in the off-state.

Referring to the above, the second regions 12 of the superjunction region 10 are electrically coupled to the source node S. In the example illustrated in FIGS. 3A-3B, each second region 12 adjoins a respective shielding region 26, so that each second region 12 is coupled to the source node S via the shielding region 26, and the body region 22 adjoining the shielding region 26.

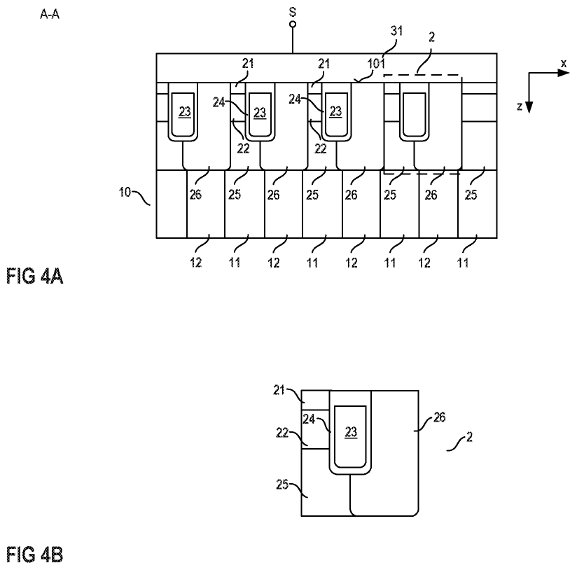

In the example illustrated in FIGS. 3A-3B, the gate electrodes 23 of two neighboring transistor cells 2 are formed by one common electrode, wherein a body region 22 of a respective transistor cell is adjacent to each of two opposite trench sidewalls of each gate trench including the common electrode. Furthermore, in the example illustrated in FIGS. 3A-3B, the body regions 22 of two transistor cells 2 are formed by one contiguous doped region, the current spreading regions 25 of two neighboring transistor cells are formed by one contiguous doped region, and each first region 11 of the superjunction region 10 is coupled to the source node S via two neighboring transistor cells 2. Implementing the transistor cells 2 in this way, however, is only an example. Another example of transistor cells 2 is illustrated in FIGS. 4A-4B.

FIG. 4A shows a vertical cross-sectional view of several transistor cells 2, and FIG. 4B shows an enlarged view of one of the transistor cells of the type illustrated in FIG. 4A. The transistor cells 2 illustrated in FIGS. 4A-4B are different from the transistor cells illustrated in FIGS. 3A-3B in that each shielding region 26 extends from the first surface 101 along a first trench sidewall of a gate trench with a gate electrode 23 arranged therein down to a respective second region 12 of the superjunction region 12. Furthermore, a body region 22 of the transistor cell 2 only adjoins an opposite second trench sidewall of the gate trench. In this example, the electrode formed in the gate trench forms the gate electrodes 23 of only one transistor cell. Furthermore, each first region 11 is connected to the source node S via only one of the transistor cells 2.

The transistor device can be implemented as an N-type transistor device or as a P-type transistor device. In an N-type transistor device, the doped regions of the first doping type are N-type regions and the doped regions of the second doping type are P type regions. In a P-type transistor device, the doped regions of the first doping type are P type regions and the doped regions of the second doping type are N-type regions. Referring to the above, the transistor device is a SiC transistor device. N-type dopants in SiC are nitrogen (N), phosphorous (P) or arsenic (As) atoms, for example. P-type dopants in SiC are boron (B), aluminum (Al) or gallium (Ga) atoms, for example.

According to one example, the doping concentration of the source regions 21 is higher than 1E19 cm⁻³. According to one example, the doping concentration of the body regions 22 is higher than 1E17 cm⁻³.

An N-type transistor device, for example, can be operated in the on-state or the off-state when the drain-source voltage is a positive voltage. An N-type transistor device is in the diode state when the drain-source voltage is a negative voltage.

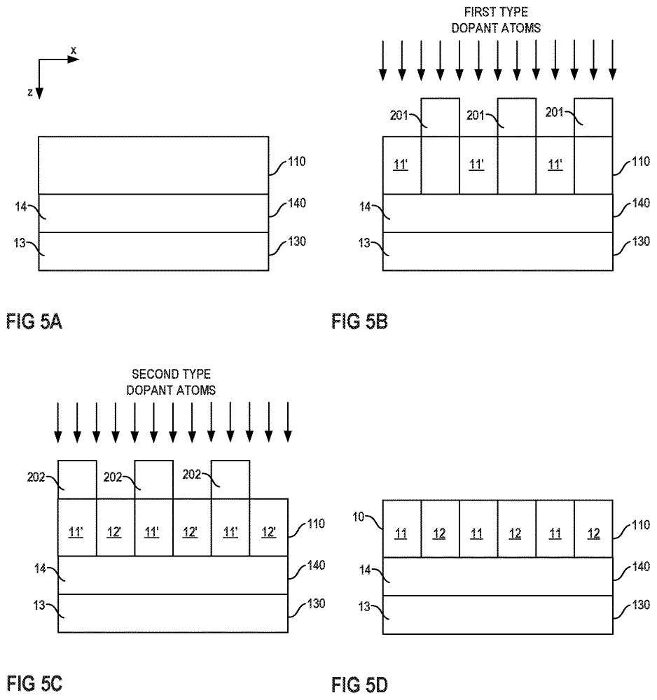

FIGS. 5A-5D illustrate one example of a method for forming the superjunction region 10 with the first and second regions 11, 12. Each of FIGS. 5A-5D illustrates a cross-sectional view of a portion of the semiconductor body 100 during the manufacturing process.

Referring to FIG. 5A, the method includes providing a carrier on top of which the superjunction region 10 is to be formed. According to one example, the carrier includes a first semiconductor layer 130 forming the drain region 13 in the finished device and a second semiconductor layer 140 forming the buffer region 14 in the finished device, wherein the second semiconductor layer 140 is formed on top of the first semiconductor layer 130. According to one example, the first semiconductor layer 130 is a semiconductor substrate having a doping concentration that equals the desired doping concentration of the drain region 13, and the second semiconductor layer 140 is an epitaxial layer formed on top of the substrate in an epitaxial growth process. According to one example, the second semiconductor layer 140 is in-situ doped during the epitaxial growth process to obtain the desired doping concentration of the buffer region 14. Referring to the above, the buffer region 14 may include two or more differently doped sections. This can be achieved by forming two or more epitaxial layers with different doping concentrations one above the other. Alternatively, the buffer region 14 is formed based on one semiconductor layer which is in-situ doped such that the doping concentration decreases during the epitaxial growth process.

The optional drift region 15 may be formed by a further epitaxial layer grown on top of the epitaxial layer forming the buffer region 14.

Referring to FIG. 5A, the method further includes forming a third semiconductor layer 110 on top of the second semiconductor layer 140. According to one example, the third semiconductor layer 110 is intrinsic or has a basic doping concentration lower than 1E16 cm⁻³.

The method further includes forming the first and second regions 11, 12 in the third semiconductor layer 110. Referring to FIG. 5B, forming the first regions 11 includes implanting first type dopant atoms into the third semiconductor layer 110. Referring to FIG. 5C, forming the second regions 12 includes implanting second type dopant atoms into the third semiconductor layer 110.

Referring to FIG. 5B, implanting the first type dopant atoms includes using a first implantation mask 201 that covers first portions of a surface of the third semiconductor layer 110 and leaves second portions of the surface uncovered. The first type dopant atoms are implanted into the surface of the third semiconductor layer 110 through the first implantation mask 201, so that first type dopant atoms essentially are implanted only into those sections of the surface not covered by the first implantation mask 201. Regions of the third semiconductor layer 110 into which first type dopant atoms are implanted are referred to as first implanted regions 11′ in the following. The first implantation mask 201 defines the position and the size of the first implanted regions 11′ in lateral directions of the third semiconductor layer 110. “Lateral directions” of the third semiconductor layer 110 are directions that are essentially perpendicular to the direction in which the first, second, and third semiconductor layers 130, 140, 110 are arranged one above the other.

Referring to FIG. 5C, implanting the second type dopant atoms includes using a second implantation mask 202 that covers third portions of the surface of the third semiconductor layer 110 and leaves fourth portions of the surface uncovered. Referring to FIG. 5C the second type dopant atoms are implanted into the surface of the third semiconductor layer 110 through the second implantation mask 201, so that second type dopant atoms essentially are implanted only into those sections of the surface not covered by the second implantation mask 202. Regions of the third semiconductor layer 110 into which second type dopant atoms are implanted are referred to as second implanted regions 11′ in the following. The second implantation mask 202 defines the position and the size of the second implanted regions 12′ in the lateral directions of the third semiconductor layer 110.

According to one example, the third surface portions covered by the second implantation mask 202 essentially correspond to the second portions of the surface into which the first type dopant atoms have been implanted in the process illustrated in FIG. 5B. Furthermore, fourth surface portions not covered by the second implantation mask 202 essentially correspond to the first portions that were covered during the implantation process illustrated in FIG. 5B. In this example, in the finished device, first and second regions 11, 12 essentially adjoin one another.

According to another example, the first and second implantation masks 201, 202 are formed such that there are surface portions of the third semiconductor layer 110 that are covered both in the implantation process illustrated in FIG. 5B in which first type dopant atoms are implanted and the implantation process illustrated in FIG. 5C in which second type dopant atoms are implanted. In this example, the first and second regions 11, 12, in the finished device, are spaced apart from each other.

The process of implanting the first type dopant atoms into the third semiconductor layer 110 illustrated in FIG. 5B may include only one implantation process in which first type dopant atoms are implanted using essentially only one implantation energy. According to another example, the process of implanting the first type dopant atoms includes two or more implantation processes that use different implantation energies. Basically, the higher the implantation energy, the deeper the dopant atoms are implanted into the third semiconductor layer 110.

Equivalently, the process of implanting the second type dopant atoms into the third semiconductor layer 110 illustrated in FIG. 5C may include only one implantation process in which second type dopant atoms are implanted using essentially only one implantation energy. According to another example, the process of implanting the second type dopant atoms includes two or more implantation processes that use different implantation energies.

For forming the first and second regions 11, 12 based on the first and second implanted regions 11′, 12′ the method further includes an annealing process. In the annealing process, the implanted first and second type dopant atoms are activated. FIG. 5D schematically illustrates the first, second, and third semiconductor layers 130, 140, 110 after the annealing process in which the first and second regions 11, 12 are formed in the third semiconductor layer 110. It should be noted that the annealing process not necessarily takes place directly after having implanted the first and second type dopant atoms. Instead, the annealing process may take place at a later stage, such as after one or more further epitaxial layers have been formed on top of the third layer 110 and after dopant atoms for forming the transistor cells 2 have been implanted.

Furthermore, it should be noted that in a SiC semiconductor body there is essentially no diffusion of the implanted first and second type dopant atoms during the annealing process. Thus, the size and the position of the first and second regions 11, 12 is essentially defined by the size and the position of the first and second implanted regions 11′, 12′ formed during the implantation processes illustrated in FIGS. 5B and 5C.

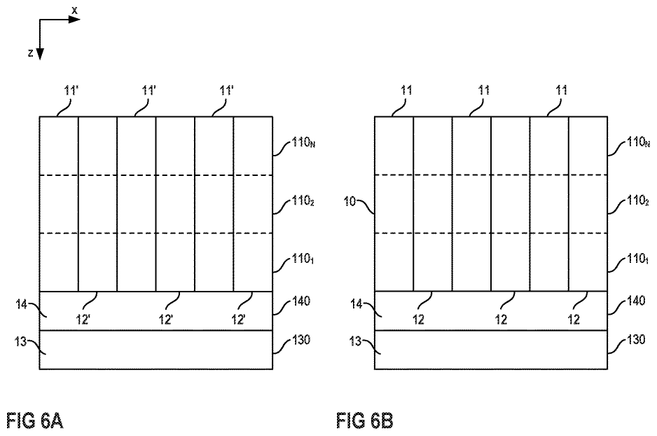

Forming the superjunction region 10 may include (a) forming one epitaxial layer on top of the second layer 140; (b) implanting the first type dopant in at least one implantation process of the type illustrated in FIG. 5B; and (c) implanting the second type dopant atoms in at least one implantation process of the type illustrated in FIG. 5C. According to another example illustrated in FIGS. number 4A-6B, forming the superjunction region 10 includes forming two or more epitaxial layers 110₁-110_{N} one above the other on top of the carrier 130, 140 and implanting first type dopant atoms and second type dopant atoms into each of the two or more epitaxial layers 110₁-110_{N} in the same way as explained with reference to FIGS. 5B-5C and before forming a next one of the two or more epitaxial layers 110₁-110_{N}. Just for the purpose of illustration, FIGS. 6A-6B illustrate three epitaxial layers 110₁-110_{N} formed one above the other.

FIG. 6A shows the arrangement after forming the epitaxial layers 110₁-110_{N} on top of the carrier 130, 240 and after implanting first and second type dopant atoms into each of the epitaxial layers 110₁-110_{N} to form portions of the first and second implanted regions 11′, 12′ in each of the epitaxial layers 110₁-110_{N}. Referring to FIG. 6A, the portions of the first regions 11′ may be formed one above the other and the portions of the second regions 12′ may formed one above the other, so that the arrangement with the two or more epitaxial layers 110₁-110_{N} includes a plurality of first implanted regions 11′ and a plurality of second implanted regions 12′ that are arranged alternatingly in the first lateral direction x.

In addition to forming the first and second implanted regions 11′, 12′ illustrated in FIG. 6A, forming the first and second regions 11, 12 further includes an annealing process. FIG. 6B shows the arrangement after the annealing process in which the first and second regions 11, 12 are formed based on the first and second implanted regions 11′, 12′. It should be noted that there is no visible border between the individual epitaxial layers 110₁-110_{N} in the finished semiconductor device. Just for the purpose of illustration, the border between the individual epitaxial layers 110₁-110_{N} is illustrated by dashed lines in FIGS. 6A-6B.

In the examples explained above, forming the first regions 11 includes at least one implantation process using at least one implantation mask and forming the second regions 12 includes at least one implantation process using at least one other implantation mask. This, however, is only an example. According to another example, the one or more third semiconductor layers 110, 110₁-110_{N} are formed to have a basic doping concentration corresponding to the desired doping concentration of the first regions 11 (or the second regions 12). In this example, the second regions 12 (or the first regions 11) are formed by implanting the respective second type (or first type) dopant atoms into the third semiconductor layers 110, 110₁-110_{N}, wherein those regions that have the basic doping concentration of the third semiconductor layers 110, 110₁-110_{N} after the at least one implantation process form the first regions 11 (or the second regions 12).

Referring to the above, the first regions 11 of the superjunction region 10 are electrically coupled to the drain region 13 and the drain node D, and the second regions 12 are electrically coupled to the source node S. As the first and second regions 11, 12 are doped regions of complementary doping types PN junctions are formed between the first and second regions 11, 12. When the transistor device is in the off-state and a drain-source voltage lower than a voltage blocking capability of the transistor device is applied between the drain and source nodes D, S space charge regions (depletion regions) expand in the first and second regions 11, 12 of the transistor device and dopant charges included in the second regions 12 “compensate” dopant charges in the first regions 11. This makes it possible to implement the first regions 11 with a higher doping concentration than the drift region of a transistor device having the same voltage blocking capability but having no second regions (compensation regions), thereby reducing the on-resistance of the transistor device including the superjunction region as compared to a conventional transistor device.

Usually, in a superjunction transistor device, which is a transistor device having a superjunction region 10, the first and second regions 11, 12 of the superjunction region 10 are balanced. This includes that in a pair of two neighboring first and second regions 11, 12 each of the first and second regions 11, 12 essentially has the same amount of dopant charges at each vertical position of the superjunction region 10. In this way, at each vertical position, dopant charges (dopant atoms) included in the first region 11 have a corresponding amount of dopant charges (dopant atoms) included in the neighboring second region 12.

The first and second regions 11, 12 of the superjunction region 10 being balanced includes that, in the first direction neighboring first and second regions 11, 12 have the same doping profile. In a vertical transistor device, the first direction corresponds to the vertical direction z of the semiconductor body 100.

However, a certain imbalance of the doping profiles may help to either increase the voltage blocking capability at a given on-resistance, or decrease the on-resistance at a given voltage blocking capability. Neighboring first and second regions 11, 12 that do not have essentially the same doping profile are referred to as imbalanced first and second regions 11, 12 in the following.

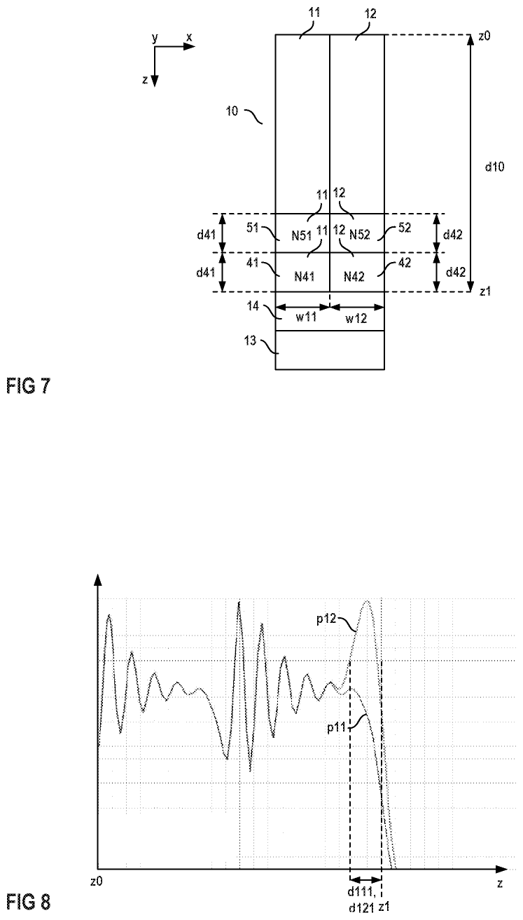

One example of imbalanced neighboring first and second regions 11, 12 is explained with reference to FIGS. 7 and 8 in the following. FIG. 7 shows a vertical cross-sectional view of two neighboring first and second regions 11, 12, and FIG. 8 shows one example of doping profiles of the neighboring first and second regions 11, 12.

Referring to FIG. 1, each of the first region 11 and the second region 12 includes an end section 41, 42 facing the drain region 13. The end section 41 of the first region 11 is referred to as first end section 41 and the end section of the second region 12 is referred to as second end section 42 in the following. In the example illustrated in FIG. 7, the transistor device includes a buffer region 14 between the drain region 13 and the superjunction region 10. In this example, the first and second end sections 41, 42 each adjoin the buffer region 14. According to another example (not illustrated) the transistor device is devoid of the buffer region 14. In this example, the first and second end sections 41, 42 each adjoin the drain region 13.

The first end section 41, which is the end section of the first region 11, has a first effective amount N41 of first type dopant atoms. The first end section 41 may include a certain amount of second type dopant atoms, wherein the amount of first type dopant atoms prevails. The “effective amount N41 of first type dopant atoms” is the difference between the overall amount of first type dopant atoms and the overall amount of second type dopant atoms in the first end section 41.

Equivalently, the second end section 42, which is the end section of the second region 12, has a second effective amount N42 of second type dopant atoms. The second end section 42 may include a certain amount of first type dopant atoms, wherein the amount of second type dopant atoms prevails. The “effective amount N42 of second type dopant atoms” is the difference between the overall amount of second type dopant atoms and the overall amount of first type dopant atoms in the second end section 42.

In the superjunction region 10 illustrated in FIGS. 7 and 8, the doping profiles of the first and second regions 11, 12 are imbalanced. In this example, the imbalance of the doping profile includes that the second effective amount N42 of second type dopant atoms in the second end section 42 is at least 1.1 times the first effective amount N41 of first type dopant atoms in the first end section 41,

N42>1.1·N41 (1),

so that a ratio between the second effective amount N42 and the first effective amount N41 is at least 1.1, N42/N41≥1.1. According to one example, the ratio is at least 1.2 or at least 1.5.

According to one example, the first end section 41 and the second end section 42 at least approximately have the same dimension in the first direction of the semiconductor body, which is vertical direction z in the example illustrated in FIG. 7. Thus, d41≈d42, wherein d41 denotes the dimension of the first end section 41 and d42 denotes the dimension of the second end section 42 in the first direction z. In the first direction z, dimensions d41, d42 of the first and second end sections are in a range of between 0.2 micrometers and 0.4 micrometers, for example.

Furthermore, the first end section 41 and the second end section 42 may have at least approximately the same dimension in a third direction perpendicular to the first direction z and the second direction x. Referring to the above, the second direction x is the direction in which the first and second regions 11, 12 are arranged alternatingly and, therefore, is the direction in which neighboring first and second regions 11, 12 are arranged next to each other. In the example illustrated in FIG. 7, the second direction is the first lateral direction x. Consequently, the third direction is the second lateral direction y.

In the second direction x, the first and second regions 11, 12 may have the same dimension. That is, a width w11 of the first region 11 may be equal to a width w12 of the second region 12. This, however, is only an example. It is also possible to implement neighboring first and second regions 11, 12 with different widths w11, w12. The widths of the first and second regions 11, 12 are selected from a range of between 0.5 micrometers (μm) and 1 micrometer, for example.

FIG. 8 illustrates doping profile of neighboring first and second regions 11, 12 that are imbalanced in such a way that the second end section 42 has a second effective amount N42 of second type dopant atoms which is at least 1.1 times a first effective amount N41 of first type dopant atoms in the first end section 41. In FIG. 8, curve p11 illustrates the specific effective amount of first type dopant atoms in the first region 11 at vertical positions between a first vertical position z0 and a second vertical position z1, and curve p12 illustrates the specific effective amount of second type dopant atoms in the second region 12 at vertical positions between the first vertical position z0 and the second vertical position z1.

The first vertical position z0 denotes the position of an interface between the superjunction region 10 and the transistor cells, and the second vertical position z1 denotes the position of an interface between the superjunction region 10 and the buffer region 14 or the drain region 13. The “specific effective amount of first type dopant atoms” is the effective amount of first type dopant atoms at a certain vertical position of the first region 11, and the “specific effective amount of second type dopant atoms” is the effective amount of second type dopant atoms at a certain vertical position of the second region 12. The first effective amount of first type dopant atoms in the first end section 41 is given by the integral of the specific effective amount of first type dopant atoms over the dimension d41 of the first end section 41 in the first direction z, and the second effective amount of second type dopant atoms in the second end section 42 is given by the integral of the specific effective amount of second type dopant atoms over the dimension of the second end section 42 in the first direction z.

As can be seen from FIG. 8, the specific effective amount of first type dopant atoms in the first region 11 indicated by profile p11 and the specific amount of second type dopant atoms in the second region 12 indicated by profile p12 may vary along the first direction z of the superjunction region 12. This variation of the effective amount of the first and second type dopant atoms may result from a manufacturing process of the type explained herein before in which dopant atoms are implanted into at least one epitaxial layer in at least one implantation process. The doping profile illustrated in FIG. 8 is based on an example in which two semiconductor layers have been formed one above the other and in which dopant atoms have been implanted into each of the two semiconductor layers at different implantation energies. According to one example, the first end section 41 is formed by one implantation process and the second end section is formed by another implantation process. The imbalance of the doping concentration in the first and second end sections 41, 42 can be achieved by suitably adjusting the implantation doses in the two implantation processes.

The first end section 41 has an adjoining first intermediate section 51 in the first region 11, wherein the first intermediate section 51 at least approximately has the same size as the first end section 41 in the first direction z. According to one example, the first intermediate section 51 has the same size as the first end section 41 in each direction. That is, the first intermediate section 51 has the same dimension as the first end section 41 in the first direction (vertical direction) z, the second direction (first lateral direction) x, and the third direction (second lateral direction) y. The first intermediate section 51 has an effective amount N51 of first type dopant atoms.

Equivalently, the second end section 42 has an adjoining second intermediate section 51 in the second direction 12, wherein the second intermediate section 52 at least approximately has the same size as the second end section 42 in the first direction z. According to one example, the second intermediate section 52 has the same size as the second end section 42 in each direction. That is, the second intermediate section 52 has the same dimension as the second end section 42 in the first direction z, the second direction x, and the third direction y. The second intermediate section 52 has an effective amount N52 of second type dopant atoms.

Referring to the above, the effective amount N42 of second type dopant atoms in the second end section 42 is higher than the effective amount N41 of first type dopant atoms in the first end section 41. With regard to the relationship between the effective amount N42 of second type dopant atoms in the second end section 42 and the effective amount N52 of second type dopant atoms in the second intermediate section 52 and the relationship between the effective amount N41 of first type dopant atoms in the first end section 41 and the effective amount N51 of first type dopant atoms in the first intermediate section 51, there are different examples.

According a first example, the effective amount N41 of first type dopant atoms in the first end section 41 at least approximately equals the effective amount N51 of first type dopant atoms in the first intermediate section 51, and the effective amount N42 of second type dopant atoms in the second end section 42 is higher than the effective amount N52 of second type dopant atoms in the second intermediate section 52, so that

N41≈N51 (2a)

N42>N52 (2b).

According to a second example, the effective amount of first type dopant atoms in the first end section 41 is lower than the effective amount N51 of first type dopant atoms in the first intermediate section 51, and the effective amount N42 of second type dopant atoms in the second end section 42 at least approximately equals the effective amount N52 of second type dopant atoms in the second intermediate section 52, so that

N41<N51 (3a)

N42≈N52 (3b).

According to a third example, the effective amount of first type dopant atoms in the first end section 41 is higher than the effective amount N51 of first type dopant atoms in the first intermediate section 51, and the effective amount N42 of second type dopant atoms in the second end section 42 is higher than the effective amount of second type dopant atoms in the second intermediate section 52, so that

N41>N51 (4a)

N42>N52 (4b).

In each of the examples, the effective amount N51 of first type dopant atoms in the first intermediate section 51 at least approximately equals the effective amount N52 of second type dopant atoms in the second intermediate section 52, so that

N51≈N52 (5).

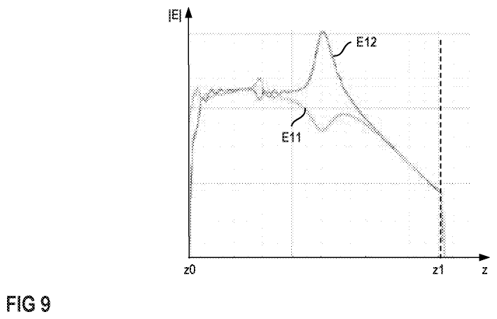

The increased doping in the second end section 42 relative to the doping in the first end section 41 results in an increased peak of the electric field in the second regions 12 of the superjunction region 10 when the transistor device is in the off-state. This increased peak of the electric field results in an increased voltage blocking capability, without increasing the on-resistance. The electric field in a first region 11 and a second region 12 in the off-state of the transistor device is illustrated in FIG. 9.

In FIG. 9, curve E11 illustrates the magnitude of the electric field |E| in the first region 11 and curve E12 illustrates the magnitude of the electric field |E| in the second region 12 when the transistor device is in the off-state. As can be seen from FIG. 9, the magnitude of the electric field in the second region 12 has a peak. Basically, the greater the imbalance of the doping profile, that is, the larger the effective amount N42 of second type dopant atoms in the second end section 42 relative to the effective amount N41 of first type dopant atoms in the first end section 41, the higher the peak of the electric field in the second region 12 and the higher the increase of the voltage blocking capability.

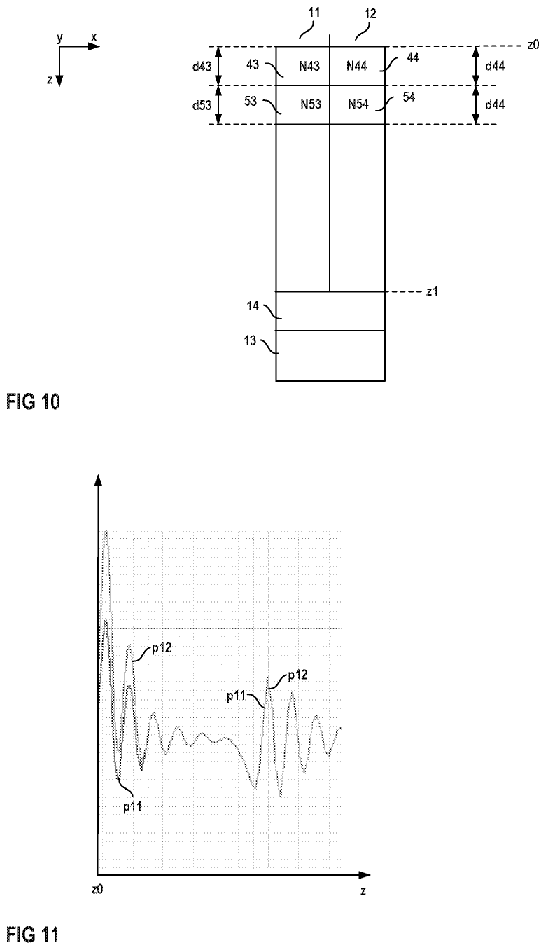

Another example of imbalanced neighboring first and second regions 11, 12 is explained with reference to FIGS. 10 and 11 in the following. FIG. 10 shows a vertical cross-sectional view of two neighboring first and second regions 11, 12, and FIG. 11 shows one example of doping profiles of the neighboring first and second regions 11, 12. The optional drift region is not illustrated in FIG. 10.

Referring to FIG. 1, each of the first region 11 and the second region 12 includes an end section 43, 44 facing the transistor cells 2 (not illustrated in FIG. 10) and facing away from the drain region 13. The end section 43 of the first region 11 is referred to as third end section 43 and the end section 44 of the second region 12 is referred to as fourth end section 44 in the following. The third end section 43 has a third effective amount N43 of first type dopant atoms, and the fourth end section 44 has a fourth effective amount of second type dopant atoms.

In the superjunction region 10 illustrated in FIGS. 10 and 11, the doping profiles of the first and second regions 11, 12 are imbalanced. In this example, the imbalance of the doping profile includes that the fourth effective amount N44 of second type dopant atoms in the fourth end section 44 is at least 1.1 times the first effective amount N43 of first type dopant atoms in the third end section 43,

N44≥1.1·N43 (6),

so that a ratio between the fourth effective amount N44 and the third effective amount N43 is at least 1.1, N44/N43≥1.1. According to one example, the ratio is at least 1.2 or at least 1.4.

According to one example, the third end section 43 and the fourth end section 44 at least approximately have the same dimension in the first direction of the semiconductor body, which is vertical direction z in the example illustrated in FIG. 10. Furthermore, the third end section 43 and the fourth end section 44 may have at least approximately the same dimension in a third direction, which is the second lateral direction y in the example illustrated in FIG. 10. In the first direction z, dimensions d43, d44 of the third and fourth end sections are in a range of between 0.2 micrometers and 0.4 micrometers, for example.

The dimension of the superjunction region 1 in the first direction is dependent on the desired voltage blocking capability of the device and is in a range of between 4 micrometers and 50 micrometers, for example.

FIG. 11 illustrates doping profiles of neighboring first and second regions 11, 12 that are imbalanced in such a way that the fourth end section 44 has a fourth effective amount N44 of second type dopant atoms which is at least 1.1 times a third effective amount N43 of first type dopant atoms in the third end section 43. In FIG. 11, curve p11 illustrates the specific effective amount of first type dopant atoms in the first region 11 at vertical positions beginning at a first vertical position z0, and curve p12 illustrates the specific effective amount of second type dopant atoms in the second region 12 at vertical positions beginning at the first vertical position z0. The first vertical position z0 denotes the position of an interface between the superjunction region 10 and the transistor cells 2. The “specific effective amount of first type dopant atoms” is the effective amount of first type dopant atoms at a certain vertical position of the first region 11, and the “specific effective amount of second type dopant atoms” is the effective amount of second type dopant atoms at a certain vertical position of the second region 12.

The third effective amount N43 of first type dopant atoms in the third end section 43 is given by the integral of the specific effective amount of first type dopant atoms over the dimension d43 of the third end section 43 in the first direction z, and the fourth effective amount N44 of second type dopant atoms in the fourth end section 44 is given by the integral of the specific effective amount of second type dopant atoms over the dimension d44 of the second end section 44 in the first direction z.

The increased amount of second type dopant atoms in the fourth end section 44 as compared to the amount of first type dopant atoms in the third end section 43 can be achieved by implanting a higher dose of second type dopant atoms into the fourth end section 44 as compared to the dose of first type dopant atoms implanted into the third end section 43.

The third end section 43 has an adjoining third intermediate section 53 in the first region 11, wherein the third intermediate section 53 at least approximately has the same size as the third end section 43. That is, the third intermediate section 53 has the same dimension as the third end section 43 in the first direction (vertical direction) z, the second direction (first lateral direction) x, and the third direction (second lateral direction) y. The third intermediate section 53 has an effective amount N53 of first type dopant atoms. Equivalently, the fourth end section 44 has an adjoining fourth intermediate section 54 in the second region 12, wherein the fourth intermediate section 54 at least approximately has the same size as the fourth end section 44. That is, the fourth intermediate section 54 has the same dimension as the fourth end section 44 in the first direction z, the second direction x, and the third direction y. The fourth intermediate section 54 has an effective amount N54 of second type dopant atoms.

Referring to the above, the effective amount N44 of second type dopant atoms in the fourth end section 44 is higher than the effective amount N43 of first type dopant atoms in the third end section 43. According to one example, the effective amount N43 of first type dopant atoms in the third end section 43 at least approximately equals the effective amount N53 of first type dopant atoms in the third intermediate section 53, and the effective amount N44 of second type dopant atoms in the fourth end section 44 is higher than the effective amount N54 of second type dopant atoms in the fourth intermediate section 54, so that

N43≈N53 (7a)

N44>N54 (7b).

In this example, the doping in the second region 12 is locally increased in the fourth end section 44, while there is no increase of the doping in the first region 11 in the third end section 43.

The local increase of the doping in the fourth end section 44 of the third region 12 makes it possible to increase the doping concentration of the current spreading regions 25 of the transistor cells without decreasing the voltage blocking capability of the transistor devices. Increasing the doping concentration of the current spreading regions 25, however, reduces the on-resistance of the transistor devices.

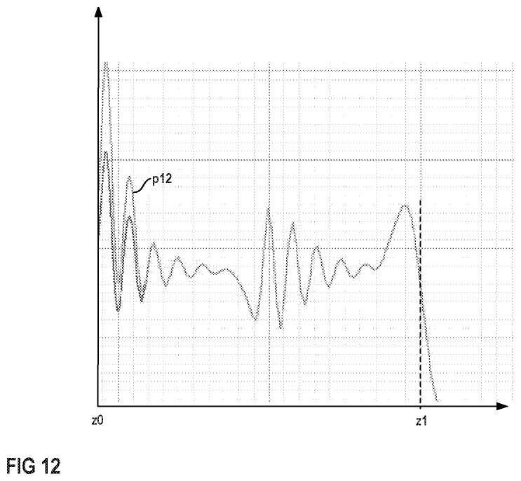

According to one example, the transistor device includes both types of imbalances explained herein before. In this example, neighboring first and second regions 11, 12 (a) include first and second end sections 41, 42, wherein the second end sections 42 have a higher effective amount of dopant atoms than the first end sections 41; and (b) include third and fourth end sections 43, 44, wherein the fourth end sections 42 have a higher effective amount of dopant atoms than the third end sections 43. FIG. 12 illustrates the effective amount of second type dopant atoms of a second region 12 in accordance with this example.

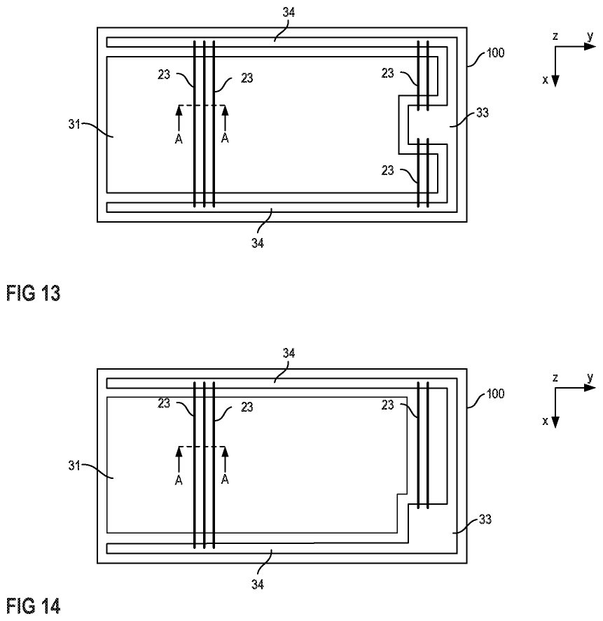

Referring to the above, the gate electrodes 23 of the transistor cells are connected to a gate node G of the transistor devices. One example for connecting the gate electrodes 23 of the transistor cells to the gate node G is illustrated in FIG. 13.

FIG. 13 shows a top view of a vertical transistor device according to one example. More specifically, FIG. 13 shows a top view of the first surface 101 of the semiconductor body 100 with the source electrode 31 arranged above the first surface 101. In addition to the source electrode 31, the transistor device includes a gate pad 33 and at least one gate runner 34 arranged above the first surface 101 of the semiconductor body 100, wherein the at least one gate runner 34 is connected to the gate pad 33. The gate pad 33 forms the gate node G or is connected to the gate node G of the transistor devices.

The transistor cells with the gate electrodes 23 are arranged below the first surface 101 and may be implemented in accordance with any of the examples illustrated in FIG. 4A-4B or 5A-5B. For the purpose of illustration, the position of the gate electrodes of some of the transistor cells are represented by bold lines in FIG. 13.

As can be seen from FIG. 13, the gate electrodes 23, in the second lateral direction y protrude from the source electrode 31 to below the gate runner 34. In the example illustrated in FIG. 13, the gate electrodes 23 protrude from the source electrode 31 on opposite ends of the source electrode 31, so that each of two opposite longitudinal ends of each gate electrode 23 is located below a respective one of two gate runners 34. Furthermore, each longitudinal and of each gate electrodes 23 is connected to the respective gate runner 34. Connections between the gate electrodes 23 and the gate runners 34 are not illustrated in FIG. 13. Such connections may include electrically conducting vias extending from the gate runners 34 down to the gate electrodes 23.

It should be noted that implementing the transistor device with two gate runners 34 such that each longitudinal end of each gate electrode 23 is connected to a respective gate runner 34 is only an example. According to another example (not illustrated) the transistor device includes only one gate runner 34, so that only one longitudinal end of each gate electrode 23 is connected to the gate runner 34.

In the example illustrated in FIG. 13, the gate pad 33 is essentially located at a position that is in the middle between the two gate runners 34. This, however, is only an example.

According to another example illustrated in FIG. 14, the gate pad 33 may be arranged essentially in one corner of the semiconductor body 100 and can therefore, closer to one of the two gate runners 34 than to the other one of the two gate runners 34.

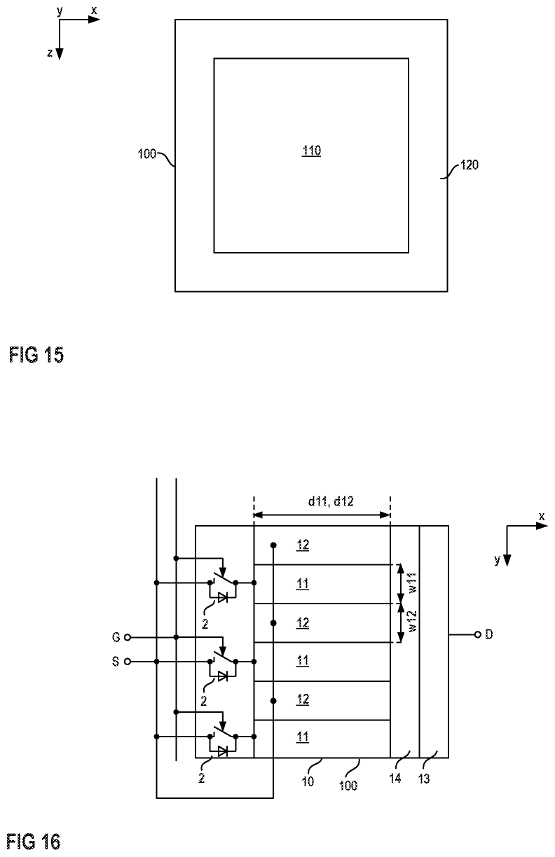

FIG. 15 schematically illustrates a horizontal cross-sectional view of the semiconductor body 100 of a vertical transistor device of the type explained herein before. Referring to FIG. 15, the semiconductor body 100 includes an inner region 110 and an edge region 120, wherein the edge region 120 surrounds the inner region 110 in lateral directions. The transistor cells 2, which are not illustrated in FIG. 15, are integrated in the inner region 110 of the semiconductor body 100. Furthermore, the source electrode 31, which is also not illustrated in FIG. 15, is arranged essentially above the inner region 110. The gate pad 33 and the at least one gate runners 34, which are not illustrated in FIG. 15, may be arranged above the edge region 120.

According to one example, the first and second end sections 41, 42 and/or the third and fourth end section 43, 44 with the imbalanced doping are arranged in the inner region 110 of the transistor devices. Portions of the superjunction region 10 may also be arranged in the edge region 120. According to one example, first and second regions 11, 12 of the superjunction region 10 arranged in the edge region 120 are balanced in view of their doping. That is, neighboring first and second regions 11, 12 arranged in the edge region 120 may essentially have the same doping profile.

In the examples explained herein before, the transistor device is a vertical transistor device, which is a transistor device in which the transistor cells 2 and the drain region 13 are spaced apart from each other in the vertical direction z of the semiconductor body 100. A transistor device with a superjunction region 10 having imbalanced first and second regions 11, 12, however, is not restricted to be implemented as a vertical transistor device. Instead, it is also possible to implement the transistor device as a lateral transistor device, which is a transistor device in which the transistor cells 2 and the drain region 13 are spaced apart from each other in a lateral direction, such as the first lateral direction x, of the semiconductor body 100. FIG. 16 schematically illustrates one example of such a lateral transistor device.

Some of the aspects explained above are briefly summarized in the following with reference to numbered examples

Example 1. A transistor device, including: a semiconductor body; a plurality of transistor cells each at least partially integrated in the semiconductor body; a drain region of a first doping type arranged in the semiconductor body; a superjunction region arranged in the semiconductor body and including a plurality of first regions of a first doping type and a plurality of second regions of a second doping type complementary to the first doping type, wherein each of the first and second regions extend in a first direction between the transistor cells and the drain region, wherein each of the first regions includes a first end section facing the drain region, wherein each of the second regions includes a second end section facing the drain region, wherein, in a pair of neighboring first and second regions, the first end section includes a first effective amount of first type dopant atoms and the second end section includes a second effective amount of second type dopant atoms, and wherein the second effective amount is at least 1.1 times the first effective amount.

Example 2. The transistor device of example 1, wherein the second effective amount is at least 1.2 times or at least 1.5 times the first effective amount.

Example 3. The transistor device of example 1 or 2, wherein a dimension of each of the first and second end sections in the first direction is between 0.2 micrometers and 0.4 micrometers.

Example 4. The transistor device of any one of examples 1 to 3, wherein, in the pair of first and second regions, the first region includes a first intermediate section adjoining the first end section and having essentially the same size in the first direction as the first end section, and wherein the first end section includes a higher effective amount of first type dopant atoms than the first intermediate section.

Example 5. The transistor device of any one of examples 1 to 3, wherein, in the pair of first and second regions, the first region includes a first intermediate section adjoining the first end section and having essentially the same size in the first direction as the first end section, and wherein the first end section includes at least approximately the same effective amount of first type dopant atoms than the first intermediate section.

Example 6. The transistor device of any one of examples 1 to 3, wherein, in the pair of first and second regions, the first region includes a first intermediate section adjoining the first end section and having essentially the same size in the first direction as the first end section, and wherein the first end section includes a lower effective amount of first type dopant atoms than the first intermediate section.

Example 7. The transistor device of any one of examples 1 to 6, wherein, in the pair of first and second regions, the second region includes a second intermediate section adjoining the second end section and having essentially the same size in the first direction as the second end section, and wherein the second end section includes a higher effective amount of second type dopant atoms than the second intermediate section.

Example 8. The transistor device of any one of examples 1 to 6, wherein, in the pair of first and second regions, the second region includes a second intermediate section adjoining the second end section and having essentially the same size in the first direction as the second end section, and wherein the second end section includes at least approximately the same effective amount of second type dopant atoms as the second intermediate section.

Example 9. The transistor device of any one of examples 4 to 8, wherein the effective amount of first type dopant atoms in the first intermediate section at least approximately equals the effective amount of second type dopant atoms in the second intermediate section.

Example 10. The transistor device of any one of examples 1 to 9, wherein each of the first regions includes a third end section facing the transistor cells, wherein each of the second regions includes a fourth end section facing the transistor cells, wherein, in a pair of neighboring first and second regions, the third end section includes a third effective amount of first type dopant atoms and the fourth end section includes a fourth effective amount of second type dopant atoms, and wherein the fourth effective amount is at least 1.1 times the third effective amount.

Example 11. The transistor device of example 10, wherein the fourth effective amount is at least 1.2 times or at least 1.4 times the third effective amount.

Example 12. A transistor device, including: a semiconductor body; a plurality of transistor cells each at least partially integrated in the semiconductor body; a drain region of a first doping type arranged in the semiconductor body; a superjunction region arranged in the semiconductor body and including a plurality of first regions of a first doping type and a plurality of second regions of a second doping type complementary to the first doping type, wherein each of the first and second regions extend in a first direction between the transistor cells and the drain region, wherein each of the first regions includes a third end section facing the transistor cells, wherein each of the second regions includes a fourth end section facing the transistor cells, wherein, in a pair of neighboring first and second regions, the third end section includes a third effective amount of first type dopant atoms and the fourth end section includes a fourth effective amount of second type dopant atoms, and wherein the fourth effective amount is at least 1.1 times the third effective amount.

Example 13. The transistor device of example 12, wherein the fourth effective amount is at least 1.2 times or at least 1.4 times the third effective amount.

Example 14. The transistor device of example 12 or 13, wherein a dimension of each of the third and fourth end sections in the first direction is between 0.2 micrometers and 0.4 micrometers.

Example 15. The transistor device of any one of examples 12 to 14, wherein, in the pair of first and second regions, the first region includes a third intermediate section adjoining the third end section and having essentially the same size in the first direction as the third end section, and wherein the third end section includes at least approximately the same effective amount of first type dopant atoms as the third intermediate section.

Example 16. The transistor device of any one of examples 10 to 13, wherein, in the pair of first and second regions, the second region includes a fourth intermediate section adjoining the fourth end section and having essentially the same size in the first direction as the fourth end section, and wherein the fourth end section includes a higher effective amount of second type dopant atoms than the fourth intermediate section.

Example 17. The transistor device of any one of examples 1 to 16, wherein each transistor cell includes: a source region of the first doping type; a body region of the second doping type; a current spreading region of the first doping type; and a gate electrode arranged adjacent to the body region and dielectrically insulated from the body region by a gate dielectric, wherein the body region is arranged between the source region and the current spreading region, and wherein the current spreading region adjoins at least one first region of the superjunction region.

Example 18. The transistor device of any one of examples 1 to 17, wherein the semiconductor body includes monocrystalline SiC.

Example 19. The transistor device of any one of examples 1 to 18, further including: a drift region of the first doping type, the drift region adjoining the superjunction region and arranged between the superjunction region and the drain region.

Example 20. The transistor device of example 19, wherein a length of the superjunction region is between 30% and70% of an overall length of the superjunction region and the drift region.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a semiconductor body;
a plurality of transistor cells at least partially integrated in the semiconductor body;
a drain region of a first doping type arranged in the semiconductor body;
a superjunction region arranged in the semiconductor body and comprising a plurality of first regions of the first doping type and a plurality of second regions of a second doping type complementary to the first doping type,
wherein each of the first and second regions extend in a first direction between the transistor cells and the drain region,
wherein each of the first regions comprises a first end section facing the drain region,
wherein each of the second regions comprises a second end section facing the drain region,
wherein in a pair of neighboring first and second regions, the first end section comprises a first effective amount of first type dopant atoms and the second end section comprises a second effective amount of second type dopant atoms, and
wherein the second effective amount is at least 1.1 times the first effective amount.

2. The transistor device of claim 1, wherein the second effective amount is at least 1.2 times or at least 1.5 times the first effective amount.

3. The transistor device of claim 1, wherein a dimension of each of the first and second end sections in the first direction is between 0.2 micrometers and 0.4 micrometers.

4. The transistor device of claim 1, wherein in the pair of first and second regions, the first region comprises an intermediate section adjoining the first end section and having essentially a same size in the first direction as the first end section, and wherein the first end section comprises a higher effective amount of the first type dopant atoms than the intermediate section.

5. The transistor device of claim 1, wherein in the pair of first and second regions, the first region comprises an intermediate section adjoining the first end section and having essentially a same size in the first direction as the first end section, and wherein the first end section comprises at least approximately a same effective amount of the first type dopant atoms than the intermediate section.

6. The transistor device of claim 1, wherein in the pair of first and second regions, the first region comprises an intermediate section adjoining the first end section and having essentially a same size in the first direction as the first end section, and wherein the first end section comprises a lower effective amount of the first type dopant atoms than the intermediate section.

7. The transistor device of claim 1, wherein in the pair of first and second regions, the second region comprises an intermediate section adjoining the second end section and having essentially a same size in the first direction as the second end section, and wherein the second end section comprises a higher effective amount of the second type dopant atoms than the intermediate section.

8. The transistor device of claim 1, wherein in the pair of first and second regions, the second region comprises an intermediate section adjoining the second end section and having essentially a same size in the first direction as the second end section, and wherein the second end section comprises at least approximately a same effective amount of the second type dopant atoms as the second intermediate section.

9. The transistor device of claim 1, wherein in the pair of first and second regions, the first region comprises a first intermediate section adjoining the first end section and having essentially a same size in the first direction as the first end section, and the second region comprises a second intermediate section adjoining the second end section and having essentially a same size in the first direction as the second end section, and wherein an effective amount of the first type dopant atoms in the first intermediate section at least approximately equals an effective amount of the second type dopant atoms in the second intermediate section.

10. The transistor device of claim 1, wherein:
each of the first regions comprises a third end section facing the transistor cells;
each of the second regions comprises a fourth end section facing the transistor cells;
in a pair of neighboring first and second regions, the third end section comprises a third effective amount of the first type dopant atoms and the fourth end section comprises a fourth effective amount of the second type dopant atoms; and
the fourth effective amount is at least 1.1 times the third effective amount.

11. The transistor device of claim 10, wherein the fourth effective amount is at least 1.2 times or at least 1.4 times the third effective amount.

12. A transistor device, comprising:
a semiconductor body;
a plurality of transistor cells at least partially integrated in the semiconductor body;
a drain region of a first doping type arranged in the semiconductor body;
a superjunction region arranged in the semiconductor body and comprising a plurality of first regions of the first doping type and a plurality of second regions of a second doping type complementary to the first doping type,
wherein each of the first and second regions extend in a first direction between the transistor cells and the drain region,
wherein each of the first regions comprises a third end section facing the transistor cells,
wherein each of the second regions comprises a fourth end section facing the transistor cells,
wherein in a pair of neighboring first and second regions, the third end section comprises a third effective amount of first type dopant atoms and the fourth end section comprises a fourth effective amount of second type dopant atoms, and
wherein the fourth effective amount is at least 1.1 times the third effective amount.

13. The transistor device of claim 12, wherein the fourth effective amount is at least 1.2 times or at least 1.4 times the third effective amount.

14. The transistor device of claim 12, wherein a dimension of each of the third and fourth end sections in the first direction is between 0.2 micrometers and0.4 micrometers.

15. The transistor device of claim 12, wherein in the pair of first and second regions, the first region comprises a third intermediate section adjoining the third end section and having essentially a same size in the first direction as the third end section, and wherein the third end section comprises at least approximately a same effective amount of the first type dopant atoms as the third intermediate section.

16. The transistor device of claim 12, wherein in the pair of first and second regions, the second region comprises a fourth intermediate section adjoining the fourth end section and having essentially a same size in the first direction as the fourth end section, and wherein the fourth end section comprises a higher effective amount of the second type dopant atoms than the fourth intermediate section.

17. The transistor device of claim 12, wherein each transistor cell comprises:
a source region of the first doping type;
a body region of the second doping type;
a current spreading region of the first doping type; and
a gate electrode arranged adjacent to the body region and dielectrically insulated from the body region by a gate dielectric,
wherein the body region is arranged between the source region and the current spreading region, and
wherein the current spreading region adjoins at least one first region of the superjunction region.

18. The transistor device of claim 12, wherein the semiconductor body comprises monocrystalline SiC.

19. The transistor device of claim 12, further comprising:
a drift region of the first doping type, the drift region adjoining the superjunction region and arranged between the superjunction region and the drain region.

20. The transistor device of claim 19, wherein a length of the superjunction region is between 30% and 70% of an overall length of the superjunction region and the drift region.
